(19) United States
(12) Patent Application Publication
(10) Pub. No.: US 2017/0032979 A1
(43) Pub. Date: Feb. 2, 2017

(54) PRODUCTION METHOD FOR SEMICONDUCTOR PACKAGE

(71) Applicant: NITTO DENKO CORPORATION

(72) Inventors: Kosuke Morita, Ibaraki-shi (JP); Tsuyoshi Ishizaka, Ibaraki-shi (JP); Jun Ishii, Ibaraki-shi (JP); Goji Shiga, Ibaraki-shi (JP); Chie Iino, Ibaraki-shi (JP)

(21) Appl. No.: 15/105,909

(22) PCT Filed: Dec. 22, 2014
(86) PCT No.: PCT/JP2014/083899

§ 371 Date: Jun. 17, 2016

(30) Foreign Application Priority Data
Dec. 26, 2013 (JP) 2013-270084

(51) Int. Cl. H01L 21/56

(52) U.S. Cl. CPC H01L 21/561; H01L 21/568

(57) ABSTRACT

Provided is a production method for a semiconductor package which can yield a sealed resin body excellent in surface smoothness, and which makes it possible to omit any step of grinding a resin region of the sealed resin body. This method is a production method, for a semiconductor package, including the step of pressurizing a stacked body which includes: a chip-temporarily-fixed body comprising a supporting plate, a temporarily-fixing material stacked over the supporting plate, and a semiconductor chip fixed temporarily over the temporarily-fixing material; a thermosetting resin sheet arranged over the chip-temporarily-fixed body; and a separator having a tensile storage elastic modulus of 200 MPa or more at 90° C. and arranged over the thermosetting resin sheet. In this way, a sealed body is formed which includes the semiconductor chip and the thermosetting resin sheet covering the semiconductor chip.

### TECHNICAL FIELD

The present invention relates to a production method for a semiconductor package.

### BACKGROUND ART

When a semiconductor chip is sealed, a thermosetting resin sheet may be used (see, for example, Patent Document 1).

### PRIOR ART DOCUMENT

### Patent Document

Patent Document 1: JP-A-2013-7028

### SUMMARY OF THE INVENTION

### Problems to be Solved by the Invention

When a semiconductor package is produced, a process may be performed which includes: covering a semiconductor chip with a sealing resin to form a sealed resin body; curing, next, a resin region of the sealed resin body; and then grinding a surface of the sealed resin body, this surface being made of the sealed resin, to improve the surface in smoothness. If the step of grinding the sealed resin body can be omitted, the semiconductor package can be efficiently produced.

An object of the present invention is to solve this problem, and provide a production method for a semiconductor package which can yield a sealed resin body (specifically, a sealed body or a sealed structure body that will be described later) excellent in surface smoothness, and which makes it possible to omit any step of grinding a resin region of the sealed resin body.

### Means for Solving the Problems

A first aspect of the present invention relates to a production method for a semiconductor package, the method comprising:

a step of forming a sealed body by pressurizing a stacked body which comprises: a chip-temporarily-fixed body comprising a supporting plate, a temporarily-fixing material stacked over the supporting plate, and a semiconductor chip fixed temporarily over the temporarily-fixing material; a thermosetting resin sheet arranged over the chip-temporarily-fixed body; and a separator having a tensile storage elastic modulus of 200 MPa or more at 90° C. and arranged over the thermosetting resin sheet,

the sealed body comprising the semiconductor chip and the thermosetting resin sheet covering the semiconductor chip.

In the first aspect of the invention, the separator is used, which has a high tensile storage elastic modulus at 90° C., this temperature being near an ordinary temperature at which semiconductor chips are each coated with a thermosetting resin sheet. Across this separator, the thermosetting resin sheet and the others are pressurized to yield a sealed body. It is therefore possible to restrain the separator from being deformed at the time of the pressurizing, so that a surface of the sealed body that contacts the separator can be restrained from being lowered in surface smoothness by the deformation of the separator. Accordingly, the stacked body can be yielded with an excellent surface smoothness. Since the sealed body is excellent in surface smoothness, any step of grinding a resin region of the sealed body can be omitted.

In the first aspect of the invention, across this separator, the thermosetting resin sheet and the others are pressurized; thus, when these members are pressurized in a parallel-flat-plate manner, the thermosetting resin sheet can be prevented from adhering to a press machine therefor.

The separator preferably has a thickness of 35 μm to 200 μm.

The separator preferably has a surface roughness (Ra) of 300 nm or less. When the surface roughness is 300 nm or less, a mark excellent in perceptibility can be formed by laser marking.

In the step of forming the sealed body, the stacked body is pressurized preferably at a pressure of 0.5 MPa to 10 MPa.

In the step of forming the sealed body, it is preferred that the stacked body is pressurized while heated. This case makes it possible to form the sealed body easily.

In the step of forming the sealed body, the stacked body is pressurized preferably at a temperature of 70° C. to 100° C. This case makes it possible to form the sealed body easily.

It is preferred that the semiconductor package production method of the first aspect of the present invention further comprises a step of cooling the sealed body down to 60° C. or lower, and a step of peeling off the separator from the sealed body after the cooling. By peeling off the separator after the cooling, the sealed body can be prevented from being lowered in surface smoothness.

It is preferred that the semiconductor package production method of the first aspect of the present invention further comprises a step of heating the sealed body to form a cured body in which the thermosetting resin sheet is cured, and a step of peeling off the temporarily-fixing material from the cured body.

It is preferred that the semiconductor package production method of the first aspect of the present invention further comprises a step of forming a re-interconnection body by forming a re-interconnection layer on a surface of the cured body that had contacted the temporarily-fixing material.

It is preferred that the semiconductor package production method further comprises a step of making the re-interconnection body into individual pieces to yield semiconductor packages.

A second aspect of the present invention relates to a production method for a semiconductor package, the method comprising:

a step of forming a sealed structure body by pressurizing a stacked structure body which comprises: a chip mounted wafer comprising a semiconductor wafer and a semiconductor chip mounted over the semiconductor wafer; a thermosetting resin sheet arranged over the chip mounted wafer; and a separator having a tensile storage elastic modulus of 200 MPa or more at 90° C. and arranged over the thermosetting resin sheet;

the sealed structure body comprising the semiconductor wafer, the semiconductor chip mounted over the semiconductor wafer, and the thermosetting resin sheet covering the semiconductor chip.

### Effect of the Invention

According to the semiconductor package production method of each of the first and second aspects of the present invention, a sealed resin body excellent in surface smoothness can be obtained, and any step of grinding a resin region of the sealed resin body can be omitted.

### BRIEF DESCRIPTION OF THE DRAWINGS

FIG. 1 is a sectional view that schematically illustrates a state of a stacked body arranged between a lower heating plate and an upper heating plate.

FIG. 2 is a sectional view that schematically illustrates a situation that the stacked body is hot-pressed in a parallel-flat-plate manner.

FIG. 3 is a sectional view that schematically illustrates a situation that a separator is peeled off from a sealed body obtained by the hot pressing.

FIG. 4 is a schematic sectional view of the sealed body after its temporarily-fixing material is peeled off therefrom.

FIG. 5 is a sectional view that schematically illustrates a situation that a Buffer coat film is formed on a cured body.

FIG. 6 is a sectional view that schematically illustrates a situation that openings are made in the Buffer coat film in the state that a mask is arranged on the Buffer coat film.

FIG. 7 is a sectional view that schematically illustrates a situation of the cured body after the mask is removed.

FIG. 8 is a sectional view that schematically illustrates a situation that a resist is formed on a seed layer.

FIG. 9 is a sectional view that schematically illustrates a situation that a plating pattern is formed on the seed layer.

FIG. 10 is a sectional view that schematically illustrates a situation that re-interconnections are finished.

FIG. 11 is a sectional view that schematically illustrates a situation that a protective film is formed on the re-interconnections.

FIG. 12 is a sectional view that schematically illustrates a situation that openings are made in the protective film.

FIG. 13 is a sectional view that schematically illustrates a situation that electrodes are formed on the re-interconnections.

FIG. 14 is a sectional view that schematically illustrates a situation that bumps are formed on the electrodes.

FIG. 15 is a schematic sectional view of semiconductor packages obtained by dividing a re-interconnection body into individual pieces.

FIG. 16 is a sectional view that schematically illustrates a state of a stacked structure body arranged between a lower heating plate and an upper heating plate.

FIG. 17 is a sectional view that schematically illustrates a situation that the stacked structure body is hot-pressed in a parallel-flat-plate manner.

FIG. 18 is a sectional view that schematically illustrates a situation that a separator is peeled off from a sealed structure body obtained by the hot pressing.

FIG. 19 is a sectional view that schematically illustrates a situation that a ground surface is formed by grinding a wafer surface.

FIG. 20 is a schematic sectional view of a re-interconnection structure body obtained by forming a re-interconnection layer onto the ground surface.

FIG. 21 is a schematic sectional view of semiconductor packages obtained by dividing the re-interconnection structure body into individual pieces.

### MODE FOR CARRYING OUT THE INVENTION

Hereinafter, the present invention will be described in detail by way of embodiments thereof. However, the invention is not limited only to these embodiments.

### Embodiment 1

A method of Embodiment 1 makes it possible to produce a fan-out type wafer level package (WLP).

As illustrated in FIG. 1, a stacked body 1 has a chip temporarily-fixed body 11, a thermosetting resin sheet 12 arranged on the chip temporarily-fixed body 11, and a separator 13 arranged on the thermosetting resin sheet 12. The stacked body 1 is arranged between a lower heating plate 41 and an upper heating plate 42.

The chip temporarily-fixed body 11 has a supporting plate 11a, a temporarily-fixing material 11b stacked on the supporting plate 11a, and semiconductor chips 14 temporarily fixed on the temporarily-fixing material 11b.

The material of the supporting plate 11a is not particularly limited, and examples thereof include metal materials such as SUS, and plastic materials such as polyimide, polyamideimide, polyetheretherketone, and polyethersulfone.

The temporarily-fixing material 11b is not particularly limited. There is usually used a thermally peelable adhesive such as a thermally foaming adhesive since the adhesive can easily be peeled off.

The semiconductor chips 14 each have a circuit-forming surface on which electrode pads 14a are formed. The chip temporarily-fixed body 11 is in a state that the circuit-forming surfaces of the semiconductor chips 14 contact the temporarily-fixing material 11b.

The thermosetting resin sheet 12 will be later described in detail.

The tensile storage elastic modulus of the separator 13 at 90° C. is 200 MPa or more, preferably 300 MPa or more. Since the elastic modulus is 200 MPa or more, the separator 13 can be restrained from being deformed when the semiconductor chips 14 are covered. The upper limit of the tensile storage elastic modulus of the separator 13 at 90° C. is not particularly limited. The tensile storage elastic modulus of the separator 13 at 90° C. is, for example, 5000 MPa or less.

The tensile storage elastic modulus at 90° C. is measurable by a method described in the item “EXAMPLES”.

The surface roughness (Ra) of the separator 13 is preferably 300 nm or less, more preferably 200 nm or less. When the surface roughness (Ra) is 300 nm or less, a mark excellent in perceptibility can be formed by laser marking. The lower limit of the surface roughness (Ra) of the separator 13 is not particularly limited. The surface roughness (Ra) of the separator 13 is, for example, 20 nm or more.

The surface roughness (Ra) is measurable by a method described in the item “EXAMPLES”.

For the separator 13, for example, polyethylene terephthalate (PET) or polyethylene naphthalate is preferably usable.

The thickness of the separator 13 is not particularly limited, and is preferably 35 μm or more, more preferably 50 μm or more. When the thickness is 35 μm or more, the separator 13 can be prevented from being bent to be deformed so that a good shaped body can be yielded. The thickness of the separator 13 is preferably 200 μm or less, more preferably 100 μm or less. When the thickness is 200 μm or less, the separator is easily cut and worked to be excellent in practicality.

As illustrated in FIG. 2, the lower heating plate 41 and the upper heating plate 42 are used to hot-press the stacked body 1 in a parallel-flat-plate manner to form a sealed body 51.

The temperature for the hot pressing is preferably 70° C. or higher, more preferably 80° C. or higher, even more preferably 85° C. or higher. When the temperature is 70° C. or higher, the thermosetting resin sheet 12 can be melted so that the stacked body can be sealed therewith without generating voids. The temperature for the hot pressing is preferably 100° C. or lower, more preferably 95° C. or lower. When the temperature is 100° C. or lower, the shaped body can be restrained from being warped.

The pressure for hot-pressing the stacked body 1 is preferably 0.5 MPa or more, more preferably 1 MPa or more. When the pressure is 0.5 MPa or more, the stacked body can be sealed therewith without generating voids. The pressure for hot-pressing the stacked body 1 is preferably 10 MPa or less, more preferably 8 MPa or less. When the pressure is 10 MPa or less, the stacked body can be sealed without damaging the semiconductor chips 14 largely.

The period for the hot pressing is preferably 0.3 minute or longer, more preferably 0.5 minute or longer. Moreover, the period for the hot pressing is preferably 10 minutes or shorter, more preferably 5 minutes or shorter.

The hot pressing is conducted preferably in a reduced-pressure atmosphere. The hot pressing in the reduced-pressure atmosphere makes it possible to decrease the voids so that the thermosetting resin sheet can be satisfactorily embedded in the irregularities. About conditions for the reduced pressure, the pressure ranges, for example, from 0.1 to 5 kPa, preferably from 0.1 to 100 Pa.

The sealed body 51 yielded by hot-pressing the stacked body 1 has the semiconductor chips 14 and the thermosetting resin sheet 12 covering the semiconductor chips 14. The sealed body 51 contacts the temporarily-fixing material 11b and the separator 13.

Next, the sealed body 51 is cooled down to 60° C. or lower. The cooling method is not particularly limited, and is, for example, a method of allowing the sealed body 51 to stand still at ambient temperature. It is preferred to cool the sealed body 51 down to 40° C. or lower.

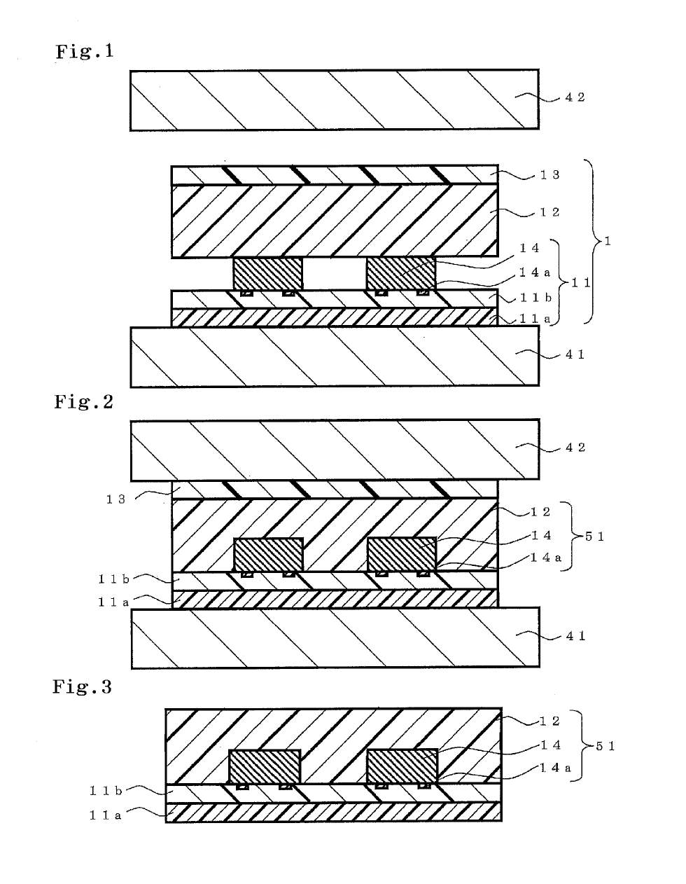

As illustrated in FIG. 3, after the cooling, the separator 13 is peeled off from the sealed body 51. The peeling of the separator 13 after the cooling makes it possible to prevent the surface smoothness from being lowered.

Next, the sealed body 51 is heated to cure the thermosetting resin sheet 12. In this way, a cured body 52 is formed.

The heating temperature is preferably 100° C. or higher, more preferably 120° C. or higher. In the meantime, the upper limit of the heating temperature is preferably 200° C. or lower, more preferably 180° C. or lower. The heating period is preferably 10 minutes or longer, more preferably 30 minutes or longer. In the meantime, the upper limit of the heating period is preferably 180 minutes or shorter, more preferably 120 minutes or shorter. When the sealed body 51 is heated, the sealed body 51 is preferably pressurized. The pressure is preferably 0.1 MPa or more, more preferably 0.5 MPa or more. In the meantime, the upper limit thereof is preferably 10 MPa or less, more preferably 5 MPa or less.

As illustrated in FIG. 4, the temporarily-fixing material 11b is heated to lower the adhesive strength of the temporarily-fixing material 11b, and subsequently the temporarily-fixing material 11b is peeled off from the cured body 52. In this way, the electrode pads 14a are made naked.

As illustrated in FIG. 5, a Buffer coat film 61 is formed onto a surface of the cured body 52 that had contacted the temporarily-fixing material 11b. For the Buffer coat film 61, for example, a photosensitive polyimide, or a photosensitive polybenzooxazole (PBO) is usable.

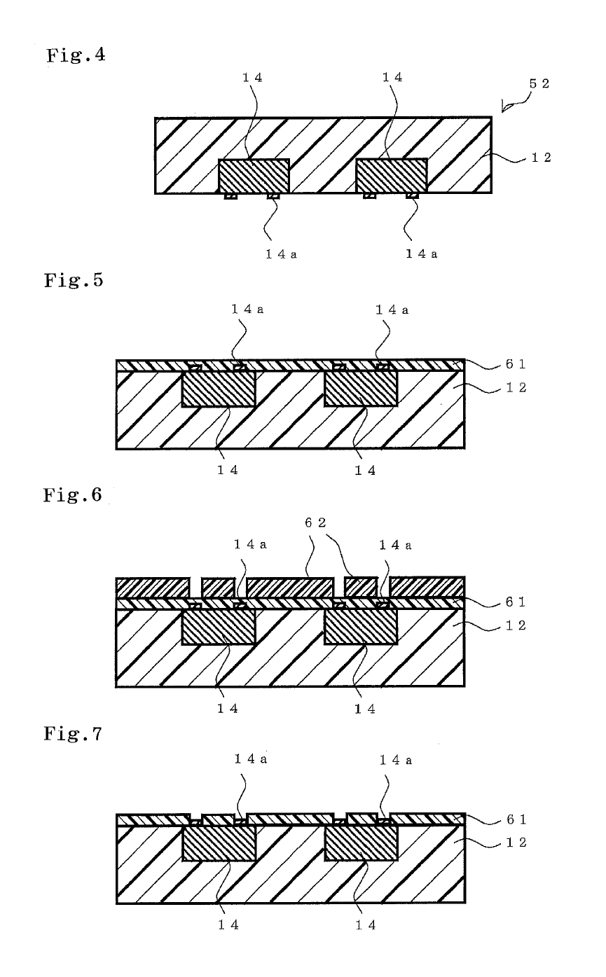

As illustrated in FIG. 6, in a state that a mask 62 is arranged on the Buffer coat film 61, the workpiece is exposed to light, developed and etched to form openings in the Buffer coat film 61. In this way, the electrode pads 14a are made naked.

Next, as illustrated in FIG. 7, the mask 62 is removed.

Next, a seed layer is formed onto the Buffer coat film 61 and the electrode pads 14a.

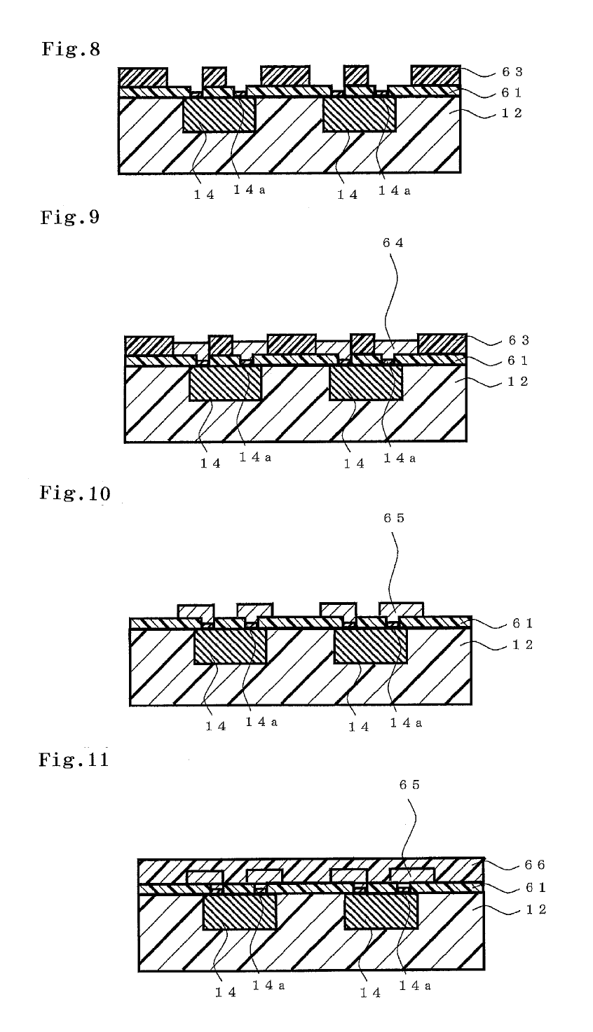

As illustrated in FIG. 8, a resist 63 is formed onto the seed layer.

As illustrated in FIG. 9, a plating pattern 64 is formed onto the seed layer by a plating method such as copper electroplating.

As illustrated in FIG. 10, the resist 63 is removed, and then the seed layer is etched to complete re-interconnections 65.

As illustrated in FIG. 11, a protective film 66 is formed onto the re-interconnections 65. For the protective film 66, for example, a photosensitive polyimide or a photosensitive polybenzooxazole (PBO) is usable.

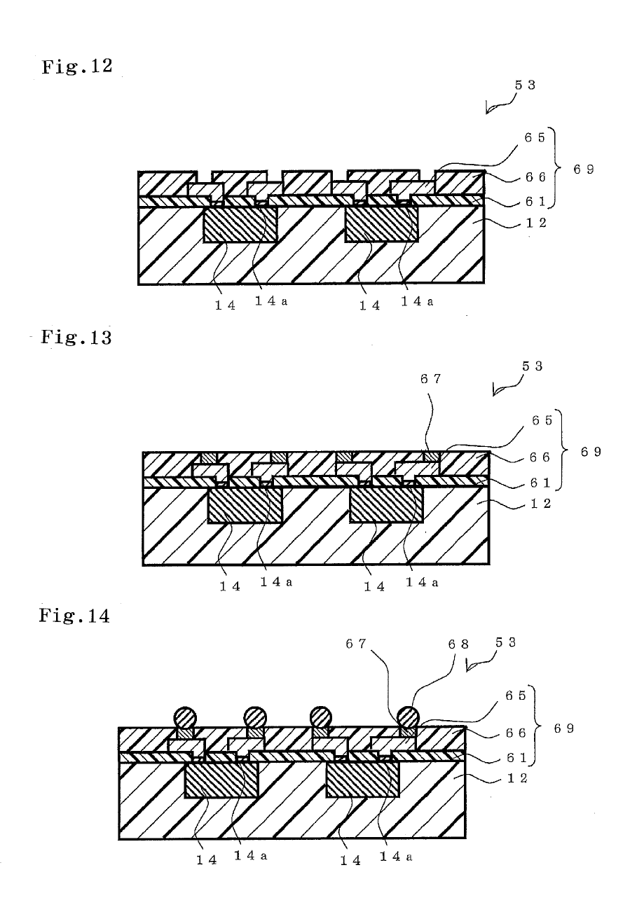

As illustrated in FIG. 12, openings are made in the protective film 66 to make the re-interconnections 65 positioned below the protective film 66 naked. In this way, a re-interconnection layer 69 including the re-interconnections 65 on the cured body 52 is finished to yield a re-interconnection body 53 having the cured body 52 and the re-interconnection layer 69 formed on the cured body 52.

As illustrated in FIG. 13, electrodes (UBM: under bump metal) 67 are formed on the naked re-interconnections 65.

As illustrated in FIG. 14, bumps 68 are formed on the electrodes 67, respectively. The bumps 68 are electrically connected through the electrodes 67 and the re-interconnections 65 to the respective electrode pads 14a.

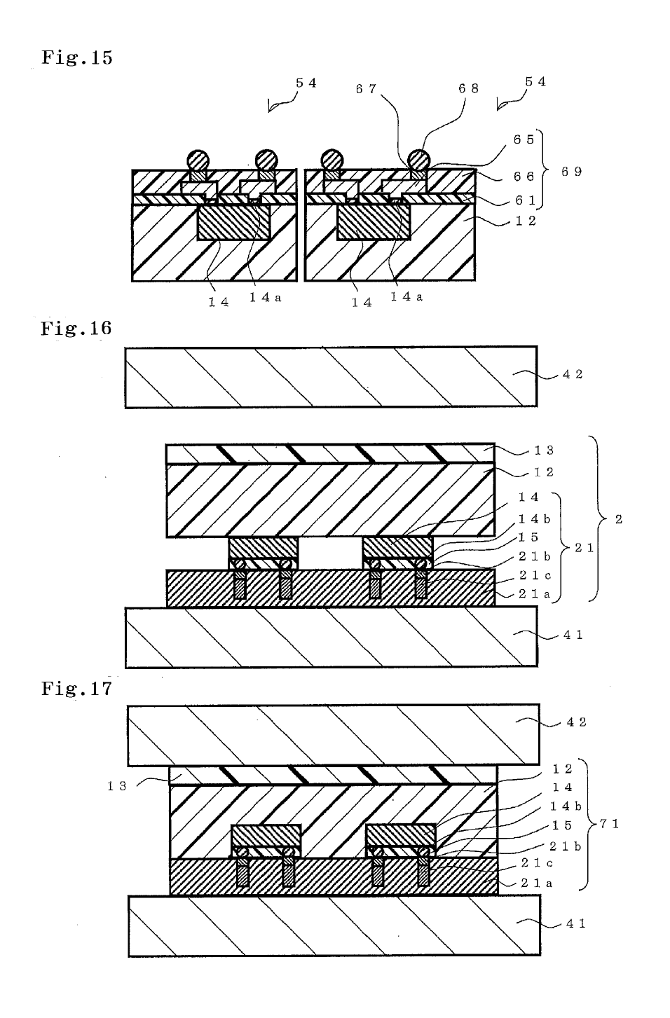

As illustrated in FIG. 15, the re-interconnection body 53 is divided (or diced) into individual pieces to yield semiconductor packages 54.

The above-mentioned process makes it possible to yield the semiconductor packages 54, in each of which some of the interconnections are led to the outside of a chip region of the package.

### Thermosetting Resin Sheet 12:

The thermosetting resin sheet 12 will be described.

The viscosity of the thermosetting resin sheet 12 at 90° C. is preferably 100000 Pa·s or less, more preferably 50000 Pa·s or less. When the viscosity is 100000 Pa·s or less, the thermosetting resin sheet 12 can be satisfactorily embedded in the irregularities. The viscosity of the thermosetting resin sheet 12 at 90° C. is preferably 100 Pa·s or more, more preferably 500 Pa·s or more, even more preferably 1000 Pa·s or more. When the viscosity is 100 Pa·s or more, the generation of voids made from, for example, out gas, can be restrained.

The viscosity at 90° C. is measurable by a method described in the item EXAMPLES.

The thermosetting resin sheet 12 has thermosetting property. The thermosetting resin sheet 12 preferably contains a thermosetting resin such as an epoxy resin or a phenolic resin.

The epoxy resin is not particularly limited, and examples thereof include triphenyl methane type epoxy resin, cresol novolak type epoxy resin, biphenyl type epoxy resin, modified bisphenol A type epoxy resin, bisphenol A type epoxy resin, bisphenol F type epoxy resin, modified bisphenol F type epoxy resin, dicyclopentadiene type epoxy resin, phenol novolak type epoxy resin, phenoxy resin, and other various epoxy resins. These epoxy resins may be used alone or in combination of two or more thereof.

In order to secure reactivity, the epoxy resin is preferably a resin which has an epoxy equivalent of 150 to 250, and has a softening point or melting point of 50 to 130° C. to be solid at room temperature. Out of species of the epoxy resin, more preferred are triphenylmethane type epoxy resin, cresol novolak type epoxy resin, and biphenyl type epoxy resin from the viewpoint of the reliability of the resin sheet. Preferred is bisphenol F type epoxy resin.

The phenolic resin is not particularly limited as long as it initiates a curing reaction with an epoxy resin. Examples thereof include a phenol novolak resin, a phenolaralkyl resin, a biphenylaralkyl resin, a dicyclopentadiene-type phenolic resin, a cresol novolak resin, and a resol resin. These phenolic resins may be used either alone or in combination of two or more thereof.

A phenolic resin having a hydroxyl equivalent of 70 to 250 and a softening point of 50° C. to 110° C. is preferably used from the viewpoint of reactivity with the epoxy resin. Among these phenolic resins, a phenol novolak resin can be preferably used from the viewpoint of its high curing reactivity. Further, a phenolic resin having low moisture absorption such as a phenolaralkyl resin and a biphenylaralkyl resin can also be suitably used from the viewpoint of its reliability.

The total content of the epoxy resin and the phenolic resin in the thermosetting resin sheet 12 is preferably 5% or more by weight. When the total content is 5% or more by weight, the sheet can satisfactorily gain an adhesive strength onto the semiconductor chips 14 and others. The total content of the epoxy resin and the phenolic resin in the thermosetting resin sheet 12 is preferably 40% or less by weight, more preferably 20% or less by weight. When the total content is 40% or less by weight, the sheet 12 can be controlled to be low in hygroscopicity.

From the viewpoint of curing reactivity, the compounding ratio of the epoxy resin to the phenolic resin is preferably set so that the total amount of the hydroxy groups in the phenolic resin is 0.7 equivalent to 1.5 equivalents, and more preferably 0.9 equivalent to 1.2 equivalents per one equivalent of the epoxy groups in the epoxy resin.

The thermosetting resin sheet 12 preferably contains a curing promoter.

The curing promoter is not particularly limited as long as it promotes curing of the epoxy resin and the phenolic resin. Examples thereof include imidazole-based curing promoters such as 2-methylimidazole (trade name; 2MZ), 2-undecylimidazole (trade name; C11-Z), 2-heptadecylimidazole (trade name; C17Z), 1,2-dimethylimidazole (trade name; 1.2DMZ), 2-ethyl-4-methylimidazole (trade name; 2E4MZ), 2-phenylimidazole (trade name; 2PZ), 2-phenyl-4-methylimidazole (trade name; 2P4MZ), 1-benzyl-2-methylimidazole (trade name; 1B2MZ), 1-benzyl-2-phenylimidazole (trade name; 1B2PZ), 1-cyanoethyl-2-methylimidazole (trade name; 2MZ-CN), 1-cyanoethyl-2-undecylimidazole (trade name; C11Z-CN), 1-cyanoethyl-2-phenylimidazolium trimellitate (trade name; 2PZCNS-PW), 2,4-diamino-6-[2′-methylimidazolyl-(1′)]-ethyl-s-triazine (trade name; 2MZ-A), 2,4-diamino-6-[2′-undecylimidazolyl-(1′)]-ethyl-s-triazine (trade name; C11Z-A), 2,4-diamino-6-[2′-ethyl-4′-methylimidazolyl-(1′)]-ethyl-s-triazine (trade name; 2E4MZ-A), 2,4-diamino-6-[2′-metthylimidazolyl-(1′)]-ethyl-s-triazine isocyanuric acid adduct (trade name; 2MA-OK), 2-phenyl-4,5-dihydroxymethylimidazole (trade name; 2PHZ-PW), and 2-phenyl-4-methyl-5-hydroxymethylimidazole (trade name; 2P4MZ-PW) (all of these compounds are manufactured by Shikoku Chemicals Corporation).

Particularly preferred are imidazole curing promoters since the promoters restrain curing reaction at the kneading temperature. More preferred are 2-phenyl-4,5-dihydroxymethylimodazole, and 2,4-diamino-6-[2′-ethyl-4′-methylimidazolyl-(1′)]ethyl-s-triazine; and even more preferred is 2-phenyl-4,5-dihydroxymethylimodazole.

The content of the curing promoter is preferably 0.2 parts or more, more preferably 0.5 parts or more, even more preferably 0.8 parts or more by weight for 100 parts by weight of the total of the epoxy resin and the phenolic resin. The content of the curing promoter is preferably 5 parts or less, more preferably 2 parts or less by weight for 100 parts by weight of the total of the epoxy resin and the phenolic resin.

The thermosetting resin sheet 12 preferably contains a thermoplastic resin (elastomer).

Examples of the thermoplastic resin include natural rubber, butyl rubber, isoprene rubber, chloroprene rubber, an ethylene-vinylacetate copolymer, an ethylene-acrylic acid copolymer, an ethylene-acrylate copolymer, a polybutadiene resin, a polycarbonate resin, a thermoplastic polyimide resin, polyamide resins such as 6-nylon and 6,6-nylon, a phenoxy resin, an acrylic resin, saturated polyester resins such as PET and PBT, a polyamideimide resin, a fluoro resin, a styrene-isobutylene-styrene triblock copolymer, and a methylmethacrylate-butadiene-styrene copolymer (MBS resin). These thermoplastic resins may be used alone or in combination of two or more thereof.

The content of the thermoplastic resin(s) in the thermosetting resin sheet 12 is preferably 1% or more by weight. When the content is 1% or more by weight, softness and flexibility can be given to the sheet 12. The content of the thermoplastic resin(s) in the thermosetting resin sheet 12 is preferably 30% or less, more preferably 10% or less, even more preferably 5% or less by weight. When the content is 30% or less by weight, the sheet 12 can satisfactorily gain adhering strength to the semiconductor chips 14 and others.

The thermosetting resin sheet 12 preferably contains an inorganic filler. By incorporating the inorganic filler thereinto, the sheet 12 can be decreased in thermal expansion coefficient α.

Examples of the inorganic filler include quartz glass, talc, silica (fused silica, crystalline silica, etc.), alumina, aluminum nitride, silicon nitride, and boron nitride. Among these inorganic fillers, silica and alumina are preferable, and silica is more preferable because the thermal expansion coefficient can be reduced well. Silica is preferably fused silica and more preferably spherical fused silica because of its excellent fluidity.

The average particle size of the inorganic filler is preferably 5 μm or more. If the average particle size is 5 μm or more, the flexibility and softness of the thermosetting resin sheet 12 can be easily obtained. The average particle size of the inorganic filler is preferably 50 μm or less, and more preferably 30 μm or less. If the average particle size is 50 μm or less, a high filling rate of the inorganic filler can be easily obtained.

For example, the average particle size can be measured by using a laser diffraction-scattering type particle size distribution measuring apparatus on a sample that is arbitrarily extracted from a population.

The inorganic filler is preferably treated (pretreated) with a silane coupling agent. By this treatment, wettability of the inorganic filler to the resin can be improved, and dispersibility of the inorganic filler can be enhanced.

The silane coupling agent is a compound having a hydrolyzable group and an organic functional group in a molecule.

Examples of the hydrolyzable group include alkoxy groups having 1 to 6 carbon atoms such as a methoxy group and an ethoxy group, an acetoxy group, and a 2-mthoxyrthoxy group. Among these, a methoxy group is preferable because it is easy to remove a volatile component such as an alcohol generated by hydrolysis.

Examples of the organic functional group include a vinyl group, an epoxy group, a styryl group, a methacrylic group, an acrylic group, an amino group, a ureido group, a mercapto group, a sulfide group, an isocyanate group. Among these, an epoxy group is preferable because the epoxy group can easily react with an epoxy resin and a phenolic resin.

Examples of the silane coupling agent include vinyl group-containing silane coupling agents such as vinyltrimethoxysilane and vinyltriethoxysilane; epoxy group-containing silane coupling agents such as 2-(3,4-epoxycyclohexyl)ethyltrimethoxysilane and 3-glycidoxypropyl methyldimethoxysilane, 3-glycidoxypropyl trimethoxysilane, 3-glycidoxypropyl methyldiethoxysilane, and 3-glycidoxypropyl triethoxysilane; styryl group-containing silane coupling agents such as p-styryltrimethoxysilane; methacrylic group-containing silane coupling agents such as 3-methacryloxypropylmethyldimethoxysilane, 3-methacryloxypropyltrimethoxysilane, 3-methacryloxypropylmethyldiethoxysilane, and 3-methacryloxypropyltriethoxysilane; acrylic group-containing silane coupling agents such as 3-acryloxypropyltrimethoxysilane; amino group-containing silane coupling agents such as N-2-(aminoethyl)-3-aminopropylmethyldimethoxysilane, N-2-(aminoethyl)-3-aminopropyltrimethoxysilane, 3-aminopropyltrimethoxysilane, 3-aminopropyltriethoxysialne, 3-triethoxysilyl-N-(1,3-dimethyl-butylidene)propylamine, N-phenyl-3-aminopropyltrimethoxysialne, and N-(vinylbenzyl)-2-aminoethyl-3-aminopropyltrimethoxysilane; ureido group-containing silane coupling agents such as 3-ureidopropyltriethoxysilane; mercapto group-containing silane coupling agents such as 3-mercaptopropylmethyldimethoxysilane and 3-mercaptopropyltrimethoxysilane; sulfide group-containing silane coupling agents such as bis(triethoxysilylpropyl)tetrasulfide; and isocyanate group-containing silane coupling agents such as 3-isocyanatepropyltriethoxysilane.

A method of treating the inorganic filler with the silane coupling agent is not especially limited, and examples thereof include a wet method of mixing the inorganic filler and the silane coupling agent in a solvent and a dry method of treating the inorganic filler with the silane coupling agent in a gas phase.

The amount of the silane coupling agent to be used for the treatment is not especially limited; however, 0.1 to 1 part by weight of the silane coupling agent is preferably used for the treatment to 100 parts by weight of the non-treated inorganic filler.

The content of the inorganic filler in the thermosetting resin sheet 12 is preferably 20% or more, more preferably 70% or more, even more preferably 74% or more by volume. In the meantime, the content of the inorganic filler is preferably 90% or less, more preferably 85% or less by volume. When the content is 90% or less by volume, the sheet 12 can gain a good irregularity-following performance.

The content of the inorganic filler can be described by using “% by weight” as a unit. As a typical example, the content of silica is described by using “% by weight” as a unit.

The specific gravity of silica is normally 2.2 g/cm³. Therefore, a preferred range of the content (% by weight) of silica is as follows.

The content of silica in the thermosetting resin sheet 12 is preferably 81% by weight or more, and more preferably 84% by weight or more. The content of silica in the thermosetting resin sheet 12 is preferably 94% by weight or less, and more preferably 91% by weight or less.

The specific gravity of alumina is normally 3.9 g/cm³. Therefore, a preferred range of the content (% by weight) of alumina is as follows.

The content of alumina in the thermosetting resin sheet 12 is preferably 88% by weight or more, and more preferably 90% by weight or more. The content of alumina in the thermosetting resin sheet 12 is preferably 97% by weight or less, and more preferably 95% by weight or less.

Besides the components described above, the thermosetting resin sheet 12 may contain, as needed, other compounding agents generally used in manufacture of a sealing resin, such as a flame retardant component, a pigment, and a silane coupling agent.

Examples of the flame retardant component include various types of metal hydroxides such as aluminum hydroxide, magnesium hydroxide, iron hydroxide, calcium hydroxide, tin hydroxide, and complex metal hydroxides; and a phosphazene compound. Among these flame retardant components, a phosphazene compound is preferable because of its excellent flame retardancy and strength after curing.

The pigment is not particularly limited, and an example thereof is carbon black.

The method for producing the thermosetting resin sheet 12 is not particularly limited, and is preferably a method of kneading the above-mentioned individual components (for example, the epoxy resin, phenolic resin, inorganic filler and curing promoter) to yield a kneaded product, and working the product plastically into a sheet form. This method makes it possible to fill the inorganic filler highly and design the thermal expansion coefficient of the sheet 12 to a low value.

Specifically, the epoxy resin, the phenolic resin, the inorganic filler, the curing promoter, etc. are melted and kneaded using a known kneader such as a mixing roll, a pressurizing kneader, and an extruder to prepare a kneaded product, and the obtained kneaded product is subjected to plastic working to form a sheet. As kneading conditions, the upper limit of the temperature is preferably 140° C. or lower, and more preferably 130° C. or lower. The lower limit of the temperature is preferably higher than or equal to the softening point of components described above, and is 30° C. or higher, and preferably 50° C. or higher, for example. The kneading time is preferably 1 to 30 minutes. The kneading is preferably performed under a reduced pressure condition (under a reduced pressure atmosphere), and the pressure under the reduced pressure condition is 1×10⁻⁴ to 0.1 kg/cm², for example.

It is preferred to apply the plastic working to the kneaded product after the melt kneading in the state that the kneaded product keeps a high temperature without being cooled. The method for the plastic working is not particularly limited, and examples thereof include flat plate pressing, T-die extrusion, screw die extrusion, rolling, roll kneading, inflation extrusion, co-extrusion, and calendering methods. The plastic working temperature is preferably not lower than the respective softening points of the above-mentioned individual components, and is, for example, from 40 to 150° C., preferably from 50 to 140° C., more preferably from 70 to 120° C., considering the thermosetting property and the moldability of the epoxy resin.

It is also preferred to produce the thermosetting resin sheet 12 in an applying or coating manner. The thermosetting resin sheet 12 can be produced, for example, by producing an adhesive composition solution containing the above-mentioned individual components, applying the adhesive composition solution into a predetermined thickness onto a substrate separator to form a coating film, and then drying the coating film.

A solvent used for the adhesive composition solution is not particularly limited, and is preferably an organic solvent in which the individual components can be evenly dispersed, kneaded or dispersed. Examples thereof include dimethylformamide, dimethylacetoamide, N-methylpyrrolidone, ketone solvents such as acetone, methyl ethyl ketone and cyclohexanone, toluene, and xylene.

The substrate separator may be polyethylene terephthalate (PET), polyethylene or polypropylene, or a film or paper piece having a surface coated with a peeling agent such as a fluorine-containing peeling agent or a long-chain alkyl acrylate peeling agent. The method for applying the adhesive composition solution is, for example, roll coating, screen coating or gravure coating. Conditions for drying the coating film are not particularly limited, and are, for example, as follows: a drying temperature of 70 to 160° C. and a drying period of 1 to 5 minutes.

The thickness of the thermosetting resin sheet 12 is not particularly limited; however, it is preferably 100 μm or more, and more preferably 150 μm or more. The thickness of the thermosetting resin sheet 12 is preferably 2,000 μm or less, and more preferably 1,000 μm or less. If the thickness is within the above-described range, the semiconductor chip 14 can be sealed well.

As described above, the production method of Embodiment 1 for the semiconductor packages 54 includes the step of pressurizing the stacked body 1 having the chip temporarily-fixed body 11, which has the supporting plate 11a, the temporarily-fixing material 11b stacked on the supporting plate 11a and the semiconductor chips 14 fixed temporarily on the temporarily-fixing material 11b, the thermosetting resin sheet 12 arranged on the chip temporarily-fixed body 11, and the separator 13, which has a tensile storage elastic modulus of 200 MPa or more at 90° C. and is arranged on the thermosetting resin sheet 12, to form the sealed body 51, which has the semiconductor chips 14 and the thermosetting resin sheet 12 covering the semiconductor chips 14.

In the step of forming the sealed body 51, the stacked body 1 is pressurized at a temperature of, for example, 70° C. to 100° C.

The method of Embodiment 1 further includes, for example, the step of cooling the sealed body 51 down to 60° C. or lower.

The method of Embodiment 1 further includes, for example, the step of peeling off the separator 13 from the sealed body 51 after the cooling.

The method of Embodiment 1 further includes, for example, the step of heating the sealed body 51 to form the cured body 52, in which the thermosetting resin sheet 12 is cured.

The method of Embodiment 1 further includes, for example, the step of peeling off the temporarily-fixing material 11b from the cured body 52.

The method of Embodiment 1 further includes, for example, the step of forming the re-interconnection layer 69 onto the surface of the cured body 52 that had contacted the temporarily-fixing material 11b to form the re-interconnection body 53.

The method of Embodiment 1 further includes, for example, the step of dividing the re-interconnection body 53 into individual pieces to yield the semiconductor packages 54.

In method of Embodiment 1, the separator 13 is used, which is high in tensile storage elastic modulus at 90° C., this temperature being near an ordinary temperature used when the semiconductor chips 14 are coated with the thermosetting resin sheet 12. The thermosetting resin sheet 12 and the others are pressurized across the separator 13 to yield the sealed body 51. For this reason, at the time of the pressurizing, the separator 13 can be restrained from being deformed, so as to restrain the sealed-body-51-surface contacting the separator 13 from being lowered in surface smoothness by the deformation of the separator 13. Accordingly, the sealed body 51 can be obtained with an excellent surface smoothness. Since the sealed body 51 is excellent in surface smoothness, the step of grinding a resin region thereof can be omitted.

In the method of Embodiment 1, the thermosetting resin sheet 12 and the others are pressurized across the separator 13 so that the thermosetting resin sheet 12 can be prevented from adhering to the upper heating plate 42.

### Embodiment 2

As illustrated in FIG. 16, a stacked structure body 2 has a chip mounted wafer 21, a thermosetting resin sheet 12 arranged on the chip mounted wafer 21, and a separator 13 arranged on the thermosetting resin sheet 12. The stacked structure body 2 is located between a lower heating plate 41 and an upper heating plate 42.

The chip mounted wafer 21 has a semiconductor wafer 21a, and semiconductor chips 14 flip-chip-mounted (flip-chip-bonded) onto the semiconductor wafer 21a.

The semiconductor chips 14 each have a circuit-formed surface (active surface). Bumps 14b are arranged on the circuit-formed surface of the semiconductor chip 14.

The semiconductor wafer 21a has a circuit-formed surface. The circuit-formed surface of the semiconductor wafer 21a includes electrodes 21b. The semiconductor wafer 21a also has through electrodes 21c extending along the thickness direction of the semiconductor wafer 21a. The through electrodes 21c are each electrically connected to one of the electrodes 21b.

Each of the semiconductor chips 14 is electrically connected to the semiconductor wafer 21a through some of the bumps 14b and some of the electrodes 21b. An under fill material 15 is filled into between the semiconductor chips 14 and the semiconductor wafer 21a.

As illustrated in FIG. 17, the lower heating plate 41 and the upper heating plate 42 are used to hot-press the stacked structure body 2 in a parallel-flat-plate manner to form a sealed structure body 71. Preferred conditions for the hot pressing are the same as described in Embodiment 1. The hot pressing is performed preferably in a reduced-pressure atmosphere. Preferred conditions for the reduced-pressure are the same as described in Embodiment 1.

The sealed structure body 71 yielded by hot-pressing the stacked structure body 2 has the semiconductor wafer 21a, the semiconductor chips 14 flip-chip-mounted on the semiconductor wafer 21a, and the thermosetting resin sheet 12 covering the semiconductor chips 14. The sealed structure body 71 has a semiconductor-wafer-21a-arranged surface (wafer surface) and a surface opposite to the wafer surface (opposite surface). The opposite surface contacts the separator 13.

Next, the sealed structure body 71 is cooled down to 60° C. or lower. The cooling method is not particularly limited, and is, for example, a method of allowing the sealed structure body 71 to stand still at ambient temperature. The sealed structure body 71 is cooled preferably down to 40° C. or lower.

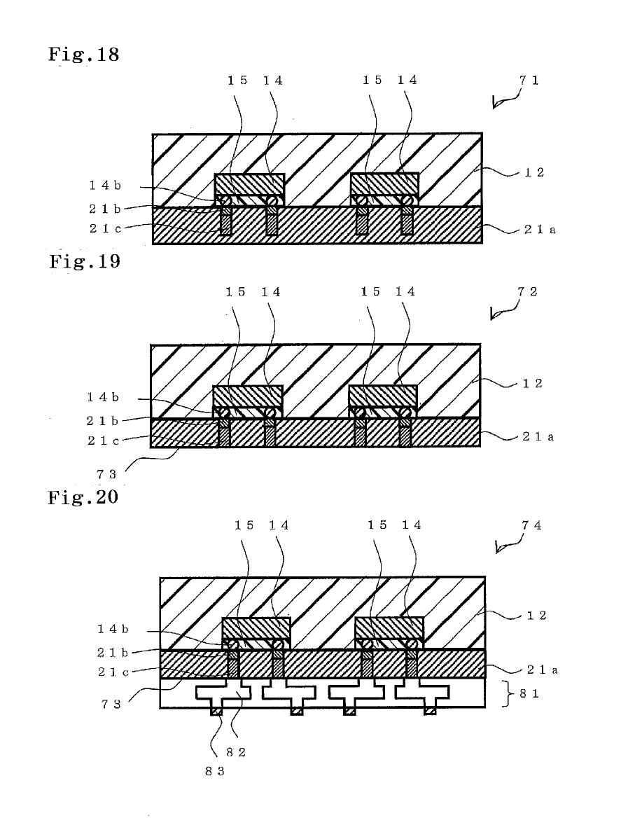

As illustrated in FIG. 18, the separator 13 is peeled off from the sealed structure body 71. By peeling off the separator 13 after the cooling, the sealed structure body 71 can be prevented from being lowered in surface smoothness.

Next, the sealed structure body 71 is heated to cure the thermosetting resin sheet 12 to forma cured structure body 72. Preferred conditions for the heating are the same as described in Embodiment 1.

As illustrated in FIG. 19, the wafer surface of the cured structure body 72 is ground to make the through electrodes 21c naked. In other words, the through electrodes 21c are naked from a ground surface 73 obtained by grinding the wafer surface.

As illustrated in FIG. 20, a semi additive method or some other method is used to form a re-interconnection layer 81 on the ground surface 73 to form a re-interconnection structure body 74. The re-interconnection layer 81 has re-interconnections 82. Next, bumps 83 are formed on the re-interconnection layer 81. The bumps 83 are each electrically connected to a bump 14b of one of the semiconductor chips 14 through one of the re-interconnections 82, one of the electrodes 21b and one of the through electrodes 21c.

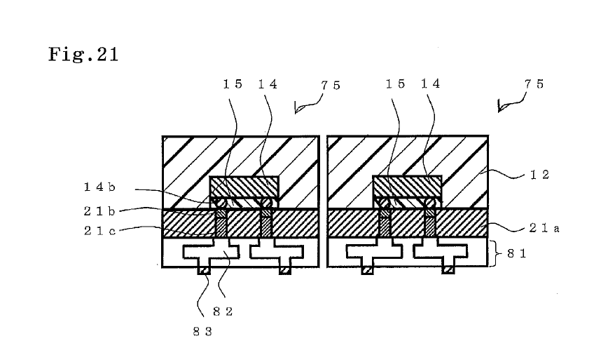

As illustrated in FIG. 21, the re-interconnection structure body 74 is divided (diced) into individual pieces. In this process, semiconductor packages 75 are yielded.

### Modified Example 1

In Embodiment 2, about the chip mounted wafer 21, the under fill material 15 is filled into between the semiconductor chips 14 and the semiconductor wafer 21a. However, in Modified Example 1, the under fill material 15 is not filled into between the semiconductor chips 14 and the semiconductor wafer 21a.

As described above, the production method of Embodiment 2 for the semiconductor packages 75 includes the step of pressurizing the stacked structure body 2 having the chip mounted wafer 21, which has the semiconductor wafer 21a and the semiconductor chips 14 mounted on the semiconductor wafer 21a, the thermosetting resin sheet 12 arranged on the chip mounted wafer 21, and the separator 13, which has a tensile storage elastic modulus of 200 MPa or more at 90° C. and is arranged on the thermosetting resin sheet 12, to form the sealed structure body 71, which has the semiconductor wafer 21a, the semiconductor chips 14 mounted on the semiconductor wafer 21a, and the thermosetting resin sheet 12 covering the semiconductor chips 14.

The method of Embodiment 2 further includes, for example, the step of cooling the sealed structure body 71 down to 60° C. or lower.

The method of Embodiment 2 further includes, for example, the step of peeling off the separator 13 from the sealed structure body 71 after the cooling.

The method of Embodiment 2 further includes, for example, the step of heating the sealed structure body 71 to form the cured structure body 72, in which the thermosetting resin sheet 12 is cured.

The method of Embodiment 2 further includes, for example, the step of grinding the semiconductor-wafer-21a-arranged surface of the cured structure body 72 to form the ground surface 73.

The method of Embodiment 2 further includes, for example, the step of forming the re-interconnection layer 81 onto the ground surface 73 to form the re-interconnection structure body 74.

The method of Embodiment 2 further includes, for example, the step of dividing the re-interconnection structure body 74 into individual pieces to yield the semiconductor packages 75.

In method of Embodiment 2, the separator 13 is used, which is high in tensile storage elastic modulus at 90° C., this temperature being near an ordinary temperature used when the semiconductor chips 14 are coated with the thermosetting resin sheet 12. The thermosetting resin sheet 12 and the others are pressurized across the separator 13 to yield the sealed structure body 71. For this reason, at the time of the pressurizing, the separator 13 can be restrained from being deformed, so as to restrain the sealed-structure-body-71-surface contacting the separator 13 from being lowered in surface smoothness by the deformation of the separator 13. Accordingly, the sealed structure body 71 can be obtained with an excellent surface smoothness. Since the sealed structure body 71 is excellent in surface smoothness, the step of grinding a resin region thereof can be omitted.

In the method of Embodiment 2, the thermosetting resin sheet 12 and the others are pressurized across the separator 13 so that the thermosetting resin sheet 12 can be prevented from adhering to the upper heating plate 42.

### EXAMPLES

Hereinafter, preferred examples of this invention will be demonstratively described in detail. However, about materials, blend amounts and others that are described in the examples, the scope of this invention is not limited only thereto unless the specification includes any restrictive description thereabout.

### [Separators]

Separators are as follows:

Separator A: DIAFOIL MRA-50 (thickness: 50 μm) manufactured by Mitsubishi Polyester Film, Inc.

Separator B: TEONEX Q51 (thickness: 50 μm) manufactured by Teijin DuPont Films Japan Ltd.

Separator C: ODZ4 (thickness: 100 μm) manufactured by Okura Industry Co., Ltd.

About the separators, evaluations described below were made. The results are shown in Table 1.

### Tensile Storage Elastic Modulus at 90° C.:

From each of the separators, a rectangular sample (a length of 30 mm×a width of 5 mm) was cut out. About this sample, the tensile storage elastic modulus was measured over temperatures from 25° C. to 200° C., using a dynamic viscoelasticity measuring instrument (RSA III, manufactured by Rheometric Scientific Inc.) in a tension measuring mode under conditions that the distance between its chucks was 23 mm and the temperature-raising rate was 10° C./minute. From the measurement result, the tensile storage elastic modulus at 90° C. was gained.

### Surface Roughness (Ra):

On the basis of JIS B 0601, the surfaced roughness (Ra) was measured, using a noncontact three-dimensional surface roughness tester (NT3300) manufactured by Veeco Instruments Inc. About a condition for the measurement, the magnifying power was set to 50. Measurement values were obtained by multiplying measured data by a median filter. The measurement was made 5 times while a site of the separator to be measured was changed. The average value thereof was defined as the surface roughness (Ra).

TABLE 1
Separator:

| | | Separator | Separator | Separator |
|---|---|---|---|---|
| | | A | B | C |
| Evaluations | Tensile storage elastic | 380 | 810 | 28 |
| | modulus (MPa) at | | | |
| | 90° C. | | | |
| | Surface roughness | 12 | 14 | 25 |
| | (nm) | | | |

### [Resin Sheets]

Resin sheets A and B are as follows:

### Components Used to Produce Resin Sheet A:

Components used to produce a resin sheet A are as follows.

Epoxy resin: YSLV-80XY, manufactured by Nippon Steel Chemical Corp. (bisphenol F type epoxy resin; epoxy equivalent: 200 g/eq., and softening point: 80° C.)

Phenolic resin: MEH-7851-SS, manufactured by Meiwa Plastic Industries, Ltd. (phenol novolak resin having a biphenylaralkyl skeleton; hydroxyl equivalent: 203 g/eq., and softening point: 67° C.)

Curing promoter: 2PHZ-PW, manufactured by Shikoku Chemicals Corp. (2-phenyl-4,5-dihydroxymethylimidazole)

Elastomer: SIBSTAR 072T, manufactured by Kaneka Corp. (styrene-isobutylene-styrene triblock copolymer)

Inorganic filler: FB-9454, manufactured by Denka Co., Ltd. (spherical fused silica powder; average particle diameter: 20 μm)

Silane coupling agent: KBM-403, manufactured by Shin-Etsu Chemical Co., Ltd. (3-glycidoxypropyltrimethoxysilane)

Carbon black: #20, manufactured by Mitsubishi Chemical Corp.

### Production of Resin Sheet A:

In accordance with blend proportions described in Table 2, individual components were blended with each other in a mixer, and then melt-kneaded at 120° C. for 2 minutes in a biaxial kneader. Subsequently, the kneaded product was extruded through a T die to produce a resin sheet A having a thickness of 500 μm.

### Components Used to Produce Resin Sheet B:

Components used to produce a resin sheet B are as follows.

Epoxy resin: KI-3000, manufactured by Tohto Kasei Co., Ltd. (o-cresol novolak type epoxy resin; epoxy equivalent: 200 g/eq)

Epoxy resin: EPIKOTE 828, manufactured by Mitsubishi Chemical Corp. (bisphenol A type epoxy resin; epoxy equivalent: 200 g/eq)

Phenolic resin: MEH-7851-SS, manufactured by Meiwa Plastic Industries, Ltd. (phenol novolak resin having a biphenylaralkyl skeleton; hydroxyl equivalent: 203 g/eq., and softening point: 67° C.)

Curing promoter: 2PHZ-PW, manufactured by Shikoku Chemicals Corp. (2-phenyl-4,5-dihydroxymethylimidazole)

Inorganic filler: FB-9454, manufacturedbyDenka Co., Ltd. (spherical fused silica powder; average particle diameter: 20 μm)

Carbon black: #20, manufactured by Mitsubishi Chemical Corp.

### Production of Resin Sheet B:

In accordance with blend proportions described in Table 2, the epoxy resins, the phenolic resin, methyl ethyl ketone (MEK) and the inorganic filler were incorporated into a container to give a solid concentration of 95%. A planetary centrifugal mixer (manufactured by Thinky Corp.) was used to stir the blend at 800 rpm for 5 minutes. Thereafter, the curing promoter and the carbon black were added thereto. Next, MEK was added thereto to give a solid concentration of 90%, and the resultant was stirred at 800 rpm for 3 minutes to yield a coating liquid. The coating liquid was applied onto a polyethylene terephthalate film (thickness: 50 μm) subjected to silicone release treatment. The coating liquid was then dried at 120° C. for 3 minutes to produce a sheet having a thickness of 100 μm. A roll laminator was used to bond plural pieces from the sheet to each other to yield a resin sheet B having a thickness of 500 μm.

About the resin sheets A and B, an evaluation described below was made. The results are shown in Table 2.

### Viscosity at 90° C.:

From each of the resin sheets A and B, a circular sample having a diameter of 20 mm and a thickness of 1.0 mm was hollowed out. A viscoelasticity measuring instrument ARES (manufactured by a company, TA Instruments) was used to measure the viscosity thereof over temperatures of 60° C. to 150° C. under the following conditions: a temperature-raising rate of 10° C./minute, a frequency of 0.1 Hz and a strain of 20%. The value of the viscosity was measured at 90° C.

TABLE 2
Resin sheet A:

| | | Resin sheet A |
|---|---|---|
| Blend | YSLV-80XY (Epoxy resin) | 453.3 |
| (parts by | MEH-7851-SS (Phenolic resin) | 479.4 |
| weight) | 2PHZ-PW (Curing promoter) | 9.3 |
| | SIBSTAR 072T (Elastomer) | 228 |
| | FB-9454 (Inorganic filler) | 8800 |
| | KBM-403 (Silane coupling agent) | 4.4 |
| | #20 (Carbon black) | 30 |
| Total (Parts by weight) | | 10004.4 |
| Evaluation | Viscosity (Pa · s) at 90° C. | 23700 |

Resin sheet B:

| | | Resin sheet B |
|---|---|---|
| Blend | KI-3000 (Epoxy resin) | 146.9 |
| (parts by | EPIKOTE 828 (Epoxy resin) | 145.3 |
| weight) | MEH-7851-SS (Phenolic resin) | 291 |
| | 2PHZ-PW (Curing promoter) | 4.5 |
| | FB-9454 (Inorganic filler) | 2706.2 |
| | #20 (Carbon black) | 9.6 |
| Total (Parts by weight) | | 3303.5 |
| Evaluation | Viscosity (Pa · s) at 90° C. | 3730 |

### Examples 1 to 4 and Comparative Examples 1 to 2

### Production of Cured Bodies

In each of the examples, a temporarily-fixing pressure-sensitive adhesive sheet (No. 3195V, manufactured by Nitto Denko Corp.) was laminated onto a glass plate (TEMPAX glass) having a size of 300 mm×400 mm×1.4 mm thickness. Next, semiconductor elements each having a size of 6 mm×6 mm×200 μm thickness were arranged at intervals of 9 mm onto the temporarily-fixing pressure-sensitive adhesive sheet. Next, either of the resin sheet species was arranged onto the semiconductor elements. Next, one of the separator species was arranged onto the resin sheet to yield a stacked body. A high-precision vacuum pressurizing apparatus (manufactured by Mikado Technos Co., Ltd.) was used to press the stacked body in a parallel-flat-plate manner at 90° C. and 2.5 MPa to yield a sealed body to which the temporarily-fixing pressure-sensitive adhesive sheet and the separator were attached. The sealed body was cooled to 40° C. and then the separator was peeled off from the sealed body.

The sealed body to which the temporarily-fixing pressure-sensitive adhesive sheet was attached was heated at 150° C. for 1 hour to cure the resin region of the sealed body to yield each cured body to which the temporarily-fixing pressure-sensitive adhesive sheet was attached. In order to lower the adhesive strength of the temporarily-fixing pressure-sensitive adhesive sheet, the cured body to which the temporarily-fixing pressure-sensitive adhesive sheet was attached was heated at 185° C. for 5 minutes, and then the temporarily-fixing pressure-sensitive adhesive sheet was peeled from the cured body.

### [Evaluation]

About the cured bodies of each of the examples, an evaluation described below was made. The result is shown in Table 3.

### Perceptibility of Characters Given by Laser Mark:

About each of some of the cured bodies, characters and a two-dimensional code were given to the resin region of the surface of the cured body that had contacted the separator.

Conditions for the laser marking were as follows:

Laser marking device: trade name “MD-S9900”, manufactured by Keyence Corp.

Wavelength: 532 nm

Intensity: 1.0 W

Scan speed: 700 mm/sec.

Q switch frequency: 64 kHz

The worked-up two-dimensional code was a code having a total size of about 4 mm×about 4 mm and having cells each having a size of 0.08 mm×0.24 mm.

When the characters of the cured body, i.e., the sample that were formed by the laser marking were visually perceptible (visual observation distance: about 40 cm) and further the code thereof was readable through a two-dimensional code reader (product name: “SR-600”, manufactured by Keyence Corp.; distance between the two-dimensional code and the two-dimensional code reader when the code was read: 10 cm or less), the sample was determined to be good (circular mark). Alternatively, when the characters formed by the laser marking were not visually perceptible, or the code was unreadable through the two-dimensional code reader, the sample was determined to be bad (cross mark). The number of the cured bodies about which this evaluation was made was 100. The proportion of readout-successful samples out of the entire samples was gained.

TABLE 3
Cured body:

| | | | | | | Comparative | Comparative |
|---|---|---|---|---|---|---|---|
| | | Example 1 | Example 2 | Example 3 | Example 4 | Example 1 | Example 2 |
| Resin sheet species | | A | A | B | B | A | B |
| Separator species | | A | B | A | B | C | C |
| Evaluation | Readout | 100 | 100 | 100 | 100 | 70 | 60 |
| | successful | | | | | | |
| | proportion | | | | | | |
| | (%) | | | | | | |

### DESCRIPTION OF REFERENCE SIGNS

1: Stacked body
11: Chip temporarily-fixed body
12: Thermosetting resin sheet
13: Separator
41: Lower heating plate
42: Upper heating plate
11a: Supporting plate
11b: Temporarily-fixing material
14: Semiconductor chip
14a: Electrode pad
51: Sealed body
52: Cured body
61: Buffer coat film
62: Mask
63: Resist
64: Plating pattern
65: Re-interconnection
66: Protective film
67: Electrode
68: Bump
69: Re-interconnection layer
53: Re-interconnection body
54: Semiconductor package
2: Stacked structure body
14b: Bump
21: Chip mounted wafer
21a: Semiconductor wafer
21b: Electrode
21c: Through electrode
15: Under fill material
71: Sealed structure body
72: Cured structure body
73: Ground surface
81: Re-interconnection layer
82: Re-interconnection
83: Bump
74: Re-interconnection structure body
75: Semiconductor package

1. A semiconductor package production method comprising:
a step of forming a sealed body by pressurizing a stacked body which comprises: a chip-temporarily-fixed body comprising a supporting plate, a temporarily-fixing material stacked over the supporting plate, and a semiconductor chip fixed temporarily over the temporarily-fixing material; a thermosetting resin sheet arranged over the chip-temporarily-fixed body; and a separator having a tensile storage elastic modulus of 200 MPa or more at 90° C. and arranged over the thermosetting resin sheet,
the sealed body comprising the semiconductor chip and the thermosetting resin sheet covering the semiconductor chip.

2. The semiconductor package production method according to claim 1, wherein the separator has a thickness of 35 μm to 200 μm.

3. The semiconductor package production method according to claim 1, wherein the separator has a surface roughness (Ra) of 300 nm or less.

4. The semiconductor package production method according to claim 1, wherein in the step of forming the sealed body, the stacked body is pressurized at a pressure of 0.5 MPa to 10 MPa.

5. The semiconductor package production method according to claim 1, wherein in the step of forming the sealed body, the stacked body is pressurized while heated.

6. The semiconductor package production method according to claim 1, wherein in the step of forming the sealed body, the stacked body is pressurized at a temperature of 70° C. to 100° C.

7. The semiconductor package production method according to claim 6, further comprising:
a step of cooling the sealed body down to 60° C. or lower, and
a step of peeling off the separator from the sealed body after the cooling.

8. The semiconductor package production method according to claim 1, further comprising:
a step of heating the sealed body to form a cured body in which the thermosetting resin sheet is cured, and
a step of peeling off the temporarily-fixing material from the cured body.

9. The semiconductor package production method according to claim 8, further comprising:
a step of forming a re-interconnection body by forming a re-interconnection layer on a surface of the cured body that had contacted the temporarily-fixing material.

10. The semiconductor package production method according to claim 9, further comprising:
a step of making the re-interconnection body into individual pieces to yield semiconductor packages.

11. A semiconductor package production method comprising:
a step of forming a sealed structure body by pressurizing a stacked structure body which comprises: a chip mounted wafer comprising a semiconductor wafer and a semiconductor chip mounted over the semiconductor wafer; a thermosetting resin sheet arranged over the chip mounted wafer; and a separator having a tensile storage elastic modulus of 200 MPa or more at 90° C. and arranged over the thermosetting resin sheet,
the sealed structure body comprising the semiconductor wafer, the semiconductor chip mounted over the semiconductor wafer, and the thermosetting resin sheet covering the semiconductor chip.
